(19) United States
(12) Patent Application Publication
(10) Pub. No.: US 2024/0250006 A1
(43) Pub. Date: Jul. 25, 2024

(54) PACKAGE STRUCTURE

(71) Applicant: Advanced Semiconductor Engineering, Inc., Kaohsiung (TW)

(72) Inventor: I-Jen CHEN, Kaohsiung (TW)

(73) Assignee: Advanced Semiconductor Engineering, Inc., Kaohsiung (TW)

(21) Appl. No.: 18/098,827

(22) Filed: Jan. 19, 2023

(51) Int. Cl. H01L 23/495

(52) U.S. Cl. CPC H01L 23/49541; H01L 23/49503

(57) ABSTRACT

The present disclosure provides a package structure. The package structure includes a die bonding region and a first lead region. The first lead region extends along a first direction. The first direction is along a first edge of the die bonding region. The first lead region includes a first high density lead region and a first low density lead region. The first high density lead region overlaps the first low density lead region in the first direction.

### BACKGROUND

### 1. Field of the Disclosure

The present disclosure relates to a package structure, in particular to a package structure including leads with different densities.

### 2. Description of Related Art

A Quad Flat No leads (QFN) structure has been developing for a requirement of more leads. One of approaches to accommodate more leads in a package structure is to reduce the size of leads. However, the lead should have a sufficient bonding area, which is restricted to alignment limitation of a wedge bonding tool, to ensure that a bonding wire can be properly bonded to the leads. In order to achieve requirements, such as high input/outputs (I/Os), high-yield production, and the like, a new package structure is required.

### SUMMARY

According to some embodiments of the present disclosure, a package structure includes a die bonding region and a first lead region. The first lead region extends along a first direction. The first direction is along a first edge of the die bonding region. The first lead region includes a first high density lead region and a first low density lead region. The first high density lead region overlaps the first low density lead region in the first direction.

According to some embodiments of the present disclosure, a package structure includes a die paddle and a first lead region. The first lead region is located at a first side of the die paddle. The first lead region includes a first inner region and a first outer region. The first inner region is closer to the die paddle than the first outer region is. A plurality of first leads are disposed within the first lead region and extend from the first outer region to the first inner region. A pitch of the plurality of first leads in the first outer region is greater than a pitch of the plurality of first leads in the first inner region.

According to some embodiments of the present disclosure, a package structure includes a die paddle, a plurality of first leads, and a plurality of second leads. At least one of the plurality of first leads has a first inner portion proximal to the die paddle and a first outer portion distal from the die paddle. At least one of the plurality of second leads has a second inner portion proximal to the die paddle and a second outer portion distal from the die paddle. From a top view, the first outer portion is aligned with the second outer portion along a first direction which is along a first edge of the die paddle, and the first inner portion overlaps the second inner portion along a second direction not parallel to the first direction.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1 illustrates a top view of a package structure according to some embodiments of the present disclosure.

FIG. 2A illustrates a partial enlarged view of the package structure as shown in FIG. 1 according to some embodiments of the present disclosure.

FIG. 2B illustrates a partial enlarged view of the package structure as shown in FIG. 1 according to some embodiments of the present disclosure.

FIG. 3 illustrates a partial enlarged view of the package structure as shown in FIG. 1 according to some embodiments of the present disclosure.

FIG. 4 illustrates a top view of a package structure according to some embodiments of the present disclosure.

FIG. 5 illustrates a top view of a package structure according to some embodiments of the present disclosure.

Common reference numerals are used throughout the drawings and the detailed description to indicate the same or similar components. The present disclosure will be more apparent from the following detailed description taken in conjunction with the accompanying drawings.

### DETAILED DESCRIPTION

The following disclosure provides many different embodiments, or examples, for implementing different features of the provided subject matter. Specific examples of components and arrangements are described below. These are, of course, merely examples and are not intended to be limiting. In the present disclosure, reference to the formation or disposal of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

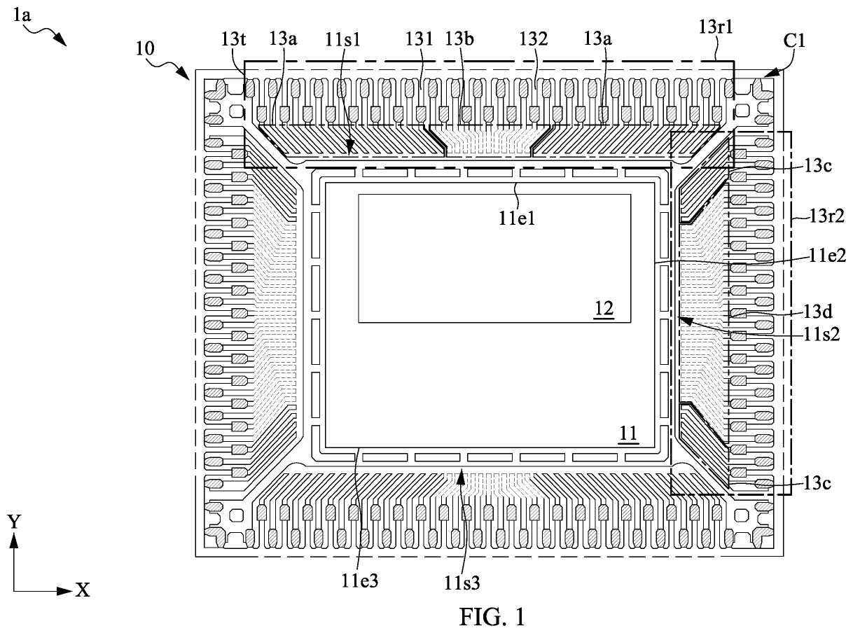

FIG. 1 illustrates a top view of a package structure 1a according to some embodiments of the present disclosure.

In some embodiments, the package structure 1a may include a lead frame 10. The lead frame 10 may be made of copper, copper alloy or another suitable metal or alloy. In some embodiments, the lead frame 10 may include one or a combination of the following: iron, nickel, iron alloy, nickel alloy or any other suitable metal or metal alloy. The lead frame 10 may include a die paddle 11, a plurality of leads 131, and a plurality of leads 132.

The die paddle 11 may be configured to, for example, provide a die bonding region 12. In some embodiments, the die paddle 11 may have an edge 11e1, an edge 11e2, and an edge 11e3. The edge 11e1 may extend along the X direction. The edge 11s2 may be adjacent to the edge 11e1 and extend along the Y direction. The edge 11e3 may extend along the X direction and be opposite to the edge 11e1. The die paddle 11 may be configured to define a side 11s1, a side 11s2, and a side 11s3. The side 11s1 may indicate a space corresponding to or adjacent to the edge 11e1. The side 11s2 may indicate a space corresponding to or adjacent to the edge 11e2. The side 11s3 may indicate a space corresponding to or adjacent to the edge 11e3.

In some embodiments, the profile and the location of the die bonding region 12 may depend on the design requirement of the package structure 1a. In some embodiments, the die bonding region 12 may be closer to the edge 11e1 than to the edge 11e3. The die bonding region 12 may be configured to support an electronic component (not shown). The die bonding region 12 may have sides (not annotated) corresponding to the side 11s1, side 11s2, and side 11s3 of the die paddle 11. For example, the die bonding region 12 may have a first side abutting the side 11s1, a second side abutting the side 11s2, and a third side abutting the side 11s3.

In some embodiments, the leads 131 and 132 may surround the die paddle 11. For example, the leads 131 and 132 may be disposed in a lead region 13r1 and in a lead region 13r2. The lead region 13r1 may face the edge 11e1 and/or be located at the side 11s1 of the die paddle 11. The lead region 13r1 may extend along the X direction. In some embodiments, the lead region 13r1 may have one or more high density lead regions 13a. In some embodiments, the lead region 13r1 may have a low density lead region 13b. The amount of leads per unit area within the high density lead region is greater than the amount of leads per unit area within the low density lead region. In some embodiments, each of the leads 131 in the lead region 13r1 may have a portion (e.g., inner portion) located within the high density lead region 13a. In some embodiments, each of the leads 132 in the lead region 13r1 may have a portion (e.g., inner portion represented by dotted lines) located within the low density lead region 13b. In some embodiments, the high density lead region 13a may laterally overlap the low density lead region 13b along the X direction. In some embodiments, the high density lead region 13a may be closer to a corner Cl of the package structure 1a in comparison with the low density lead region 13b from a top view. In some embodiments, the low density lead region 13b may be configured to prevent leads 132 from being broken. In some embodiments, the high density lead region 13a may be closer to a terminal 13t (or edge or end portion) of the lead region 13r1 from a top view. In some embodiments, the low density lead region 13b may be located between more than one high density lead regions 13a. In some embodiments, each of the lead 132 may be located between two or more leads 131. In some embodiments, the low density lead region 13b may be closer to a center of the edge 11e1 of the die paddle 11 in comparison with the high density lead region 13a. In some embodiments, the leads 131 may be closer to the corner (not annotated) of the die paddle 11 in comparison with the leads 132.

The lead region 13r2 may face the edge 11e2 and/or be located at the side 11s2 of the die paddle 11. The lead region 13r2 may extend along the Y direction. In some embodiments, the lead region 13r2 may have one or more high density lead regions 13c. In some embodiments, the lead region 13r2 may have a low density lead region 13d. In some embodiments, each of the leads 131 in the lead region 13r2 may have a portion (e.g., inner portion) located within the high density lead regions 13c. In some embodiments, each of the leads 132 in the lead region 13r2 may have a portion (e.g., inner portion represented by dotted lines) located within the low density lead region 13d. In some embodiments, the high density lead region 13c may vertically overlap the low density lead region 13d along the Y direction. In some embodiments, the high density lead region 13c may be closer to a corner Cl of the package structure 1a in comparison with the low density lead region 13d from a top view. In some embodiments, the low density lead region 13d may be located between high density lead regions 13c.

In some embodiments, the ratio of the amount between the leads 131 and 132 in the lead region 13r1 may be different from the ratio of the amount between the leads 131 and 132 in the lead region 13r2.

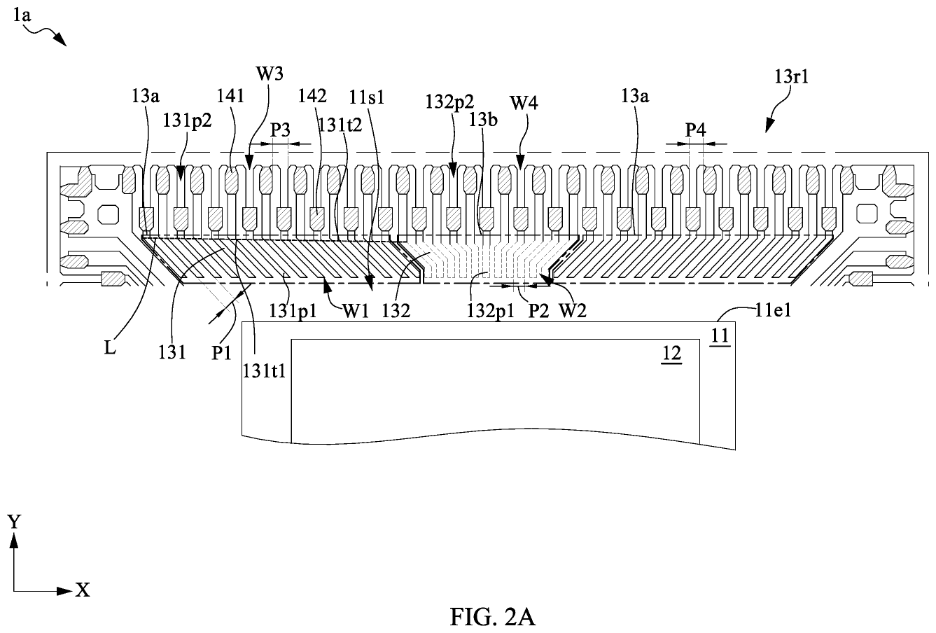

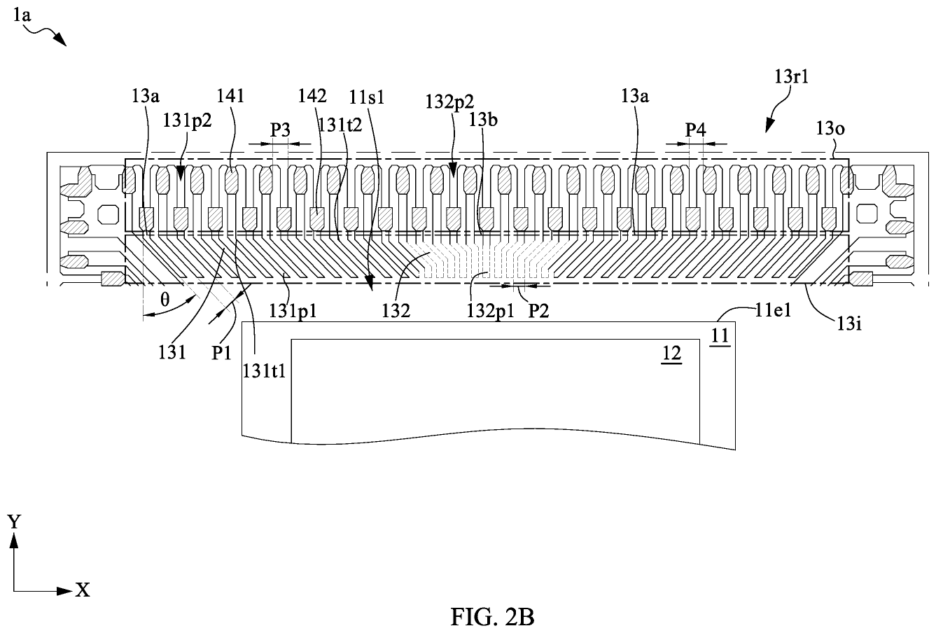

FIG. 2A illustrates a partial enlarged view of the package structure 1a as shown in FIG. 1 according to some embodiments of the present disclosure.

In some embodiments, the package structure 1a may further include a plurality of terminals 141 and a plurality of terminals 142. The terminals 141 may be aligned with each other along the X direction. The terminals 142 may be aligned with each other along the X direction. In some embodiments, the terminals 141 and 142 may be disposed in a staggered arrangement. In some embodiments, a distance between the terminal 141 and the die paddle 11 (or die bonding region 12) may be greater than a distance between the terminal 142 and the die paddle 11 (or die bonding region 12) along the Y direction. For example, the terminal 141 may be disposed farther from the die paddle 11 (or die bonding region 12) than the terminal 142 is. In some embodiments, the terminals 141 and 142 may be exposed from an encapsulant (not shown), which encapsulates the leads 131, the leads 132, and the electronic component. The terminals 141 and 142 may correspond to the portion, which is not half-etched, of the lead 131 (or 132). The terminals 141 and 142 may be attached to, for example, a motherboard (not shown) through coating solder material to connect the terminal 141 and the motherboard, or connect the terminal 142 and the motherboard.

In some embodiments, the lead 131 may have an inner portion 131p1 and an outer portion 131p2 connected to the inner portion 131p1. The inner portion 131p1 may be proximal to the die paddle 11 (or die bonding region 12). The outer portion 131p2 may be distal from die paddle 11 (or die bonding region 12). The encapsulant may entirely encapsulate the inner portion 131p1. The encapsulant may partially encapsulate the outer portion 131p2. The inner portion 131p2 may extend along the Y direction. In some embodiments, at least a portion of the inner portion 131p1 may extend along a direction oblique to the Y direction (or X direction). Each of the inner portion 131p1 of the leads 131 may have a turning point (e.g., 131t1 and/or 131t2). The turning point may be configured to define the portion of the lead 131, for example, in the lead region 13r1, extending along the Y direction and the portion of the lead 131 extending along a direction oblique to the Y direction. In some embodiments, an imaginary line L, connecting or passing the turning points 131t1 and 131t2 of the inner portion 131p1 of the leads 131, may extend a direction oblique to the X direction. In some embodiments, the turning points (e.g., 131t1 and 131t2) of the of leads 131 are arranged along a direction oblique to the edge 11e1 of the die paddle 11 from a top view.

The inner portion 131p1 may have a width W1 along the X direction. The outer portion 131p2 may have a width W3 along the X direction. In some embodiments, the width W1 may be different from the width W3. In some embodiments, the width W1 may be less than the width W3.

In some embodiments, the lead 132 may have an inner portion 132p1 and an outer portion 132p2 connected to the inner portion 132p1. The inner portion 132p1 may be proximal to the die paddle 11 (or die bonding region 12). The outer portion 132p2 may be distal from die paddle 11 (or die bonding region 12). The encapsulant may entirely encapsulate the inner portion 132p1. The encapsulant may partially encapsulate the outer portion 132p2. The outer portion 132p2 may extend along the Y direction. In some embodiments, the inner portion 132p1 may have a segment extending along a direction oblique to the Y direction (or X direction). In some embodiments, the inner portion 132p1 may have a segment extending along the Y direction. For example, the inner portion 132p1 may have a first portion extending along the Y direction. Some of the inner portions 132p1 may have a second portion extending along a direction oblique to the Y direction (or X direction).

The inner portion 132p1 may have a width W2 along the X direction. The outer portion 132p2 may have a width W4 along the X direction. In some embodiments, the width W2 may be different from the width W4. In some embodiments, the width W2 may be less than the width W4. In some embodiments, the width W1 may be less than the width W2. In some embodiments, the ratio between the width W1 and the width W2 may range from 0.85 to about 0.95, such as 0.85, 0.88, 0.91, 0.93, or 0.95. In some embodiments, the width W3 may be substantially equal to the width W4.

The inner portion 131p1 of the leads 131 may have a pitch P1. The inner portion 132p1 of the leads 132 may have a pitch P2. In some embodiments, the pitch P1 may be different from the pitch P2. In some embodiments, the pitch P1 may be less than the pitch P2. In some embodiments, the ratio between the pitch P1 and the pitch P2 may range from 0.88 to about 0.98, such as 0.88, 0.9, 0.92, 0.94, 0.96 or 0.98.

The outer portion 131p2 of the leads 131 may have a pitch P3. The outer portion 132p2 of the leads 132 may have a pitch P4. In some embodiments, the pitch P3 may be substantially equal to the pitch P4.

In some embodiments, the amount of the leads 131 may be greater than or equal to the amount of the leads 132 in the lead region 13r1.

FIG. 2B illustrates a partial enlarged view of the package structure 1a as shown in FIG. 1 according to some embodiments of the present disclosure.

In some embodiments, the lead region 13r1 may have an inner region 13i proximal to the die paddle 11 (or die bonding region 12) and an outer region 130 distal from the die paddle 11 (or die bonding region 12). The lead 131 may continuously extend from the outer region 130 to the inner region 13i. The lead 132 may continuously extend from the outer region 130 to the inner region 13i. In some embodiments, the outer portion 131p2 of the lead 131 may be located within the outer region 130 of the lead region 13r1. In some embodiments, the outer portion 132p2 of the lead 132 may be located within the outer region 130 of the lead region 13r1. In some embodiments, the inner portion 131p1 of the lead 131 may be located within the inner region 13i of the lead region 13r1. In some embodiments, the inner portion 132p1 of the lead 132 may be located within the inner region 13i of the lead region 13r1. In some embodiments, an angle θ may be defined by the inner portion 131p1 of the lead 131 and the Y direction. In some embodiments, an angle θ may be defined by the inner portion 131p1 of the lead 131 and the outer portion 131p2 of the lead 131.

Similarly, although not shown, it should be noted that the lead region 13r2 as shown in FIG. 1 may include an outer region and an inner region. The lead 131 may continuously extend from the outer region to the inner region of the lead region 13r2. The lead 132 may continuously extend from the outer region to the inner region of the lead region 13r2. In some embodiments, the outer portion of the lead 131 may be located within the outer region of the lead region 13r2. In some embodiments, the outer portion of the lead 132 may be located within the outer region of the lead region 13r2. In some embodiments, the inner portion of the lead 131 may be located within the inner region of the lead region 13r2. In some embodiments, the inner portion of the lead 132 may be located within the inner region of the lead region 13r2.

In the embodiments of this disclosure, the leads (e.g., 131 and 132) may have a hybrid pitch design to dispose wider leads in a low density lead region and to dispose narrower leads in a high density lead region, which may assist in accommodating more leads without enlarging the size of the package structure 1a. Further, since certain types of electronic component requires a specific wire bonding length in packaging structure to enhance the transmission efficiency, the conventional lead geometry shall be redesigned to accommodate this requirement. For example, the electronic component associated with receiving, processing, or transmitting radio-frequency (RF) signal, usually has specific requirements on the length of signal transmission. In the embodiments of this disclosure, the leads with hybrid pitch design may assist in lengthening at least a portion of the leads, which may reduce the distance between the leads at the corner of the lead frame and the bond pads of the electronic component to a predetermined value, thereby solving issues described above. For example, the narrower leads (e.g., 131) in the high density lead region allows the lead with more degree of freedom to deflect, thereby creating a greater turning angle θ, as shown in FIG. 2B, compared to the arrangement of the wider leads (e.g., 132). With a greater turning angle θ, even the narrower leads (e.g., 131) located close to the corner of the lead frame can have an end closer to the die paddle 11, and hence the bond pads of the electronic component, compared to the arrangement of wider leads. Furthermore, in an operation of performing a half-etching technique to etch a portion of leads, etchant may be prone to accumulating in a relatively central region with respect to a side of the lead frame, so that the leads proximal to the central region may be over-etched. Therefore, in order to prevent the leads proximal to the central region from being over-etched, the wider leads are disposed in a region proximal to the central region in comparison with the narrower leads. For example, the low density lead region 13b is closer to the center of the die paddle 11, which may enhance the yield of manufacturing the lead frame, and hence to the package structure 1a.

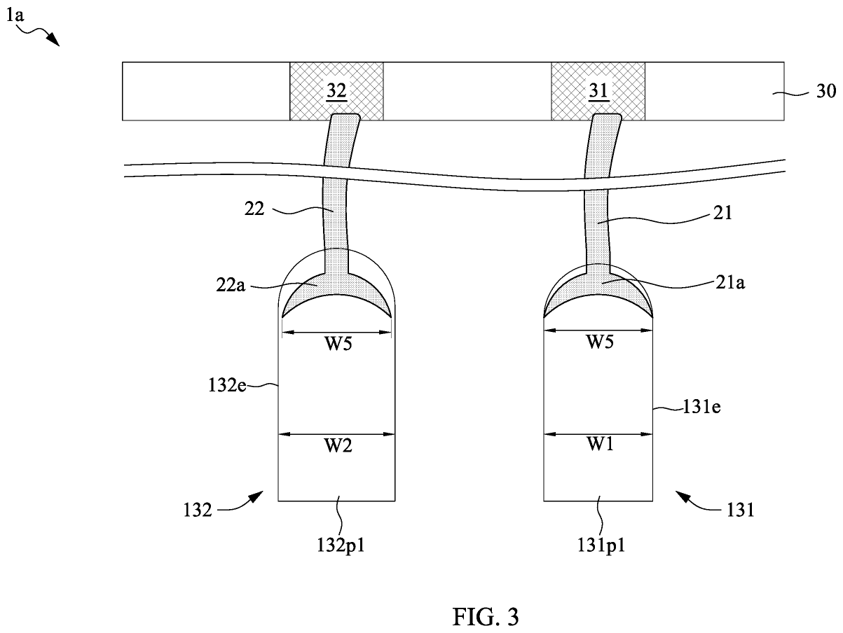

FIG. 3 illustrates a partial enlarged view of the package structure 1a as shown in FIG. 1 according to some embodiments of the present disclosure.

In some embodiments, the package structure 1a may have a wire 21, a wire 22, and an electronic component 30.

The electronic component 30 may include a semiconductor die or a chip, such as a logic die (e.g., system-on-a-chip (SoC), central processing unit (CPU), graphics processing unit (GPU), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies) or other electronic components. The electronic component 30 may be disposed over the die bonding region 12 as shown in FIG. 1.

The wire 21 may be configured to electrically connect the lead 131 to a pad 31 of the electronic component 30. The wire 22 may be configured to electrically connect the lead 132 to a pad 32 of the electronic component 30. The wire 21 may have a wedge bond 21a attached to the inner portion 131p1 of the lead 131. The wire 22 may have a wedge bond 22a attached to the inner portion 132p1 of the lead 132. Each of the wedge bonds 21a and 22a may have a width W5. In some embodiments, the width W1 of the inner portion 131p1 of the lead 131 may be substantially identical to the width W5 of the wedge bond 21a. In some embodiments, the width W2 of the inner portion 132p1 of the lead 132 may be greater than the width W5 of the wedge bond 22a. In some embodiments, the wedge bond 21a may overlap an edge 131e of the lead 131. In some embodiments, the wedge bond 21a may have a portion overlapping an edge 131e of the lead 131. In some embodiments, the wedge bond 22a may be located within the lead 132. In some embodiments, the wedge bond 22a may be free from overlapping an edge 132e of the lead 132. In some embodiments, a distance between the edge 131e of the lead 131 and the wedge bond 21a is less than a distance between the edge 132e of the lead 132 and the wedge bond 22a.

As shown in FIG. 3, the inner portion 132p1 of the lead 132 may provide a relatively large bonding area for being connected to the wire 22. Therefore, even if the lead 132 is slightly over-etched, the inner portion 132p1 of the lead 132 may have a buffer so that the wire 22 may be properly bonded to the lead 132.

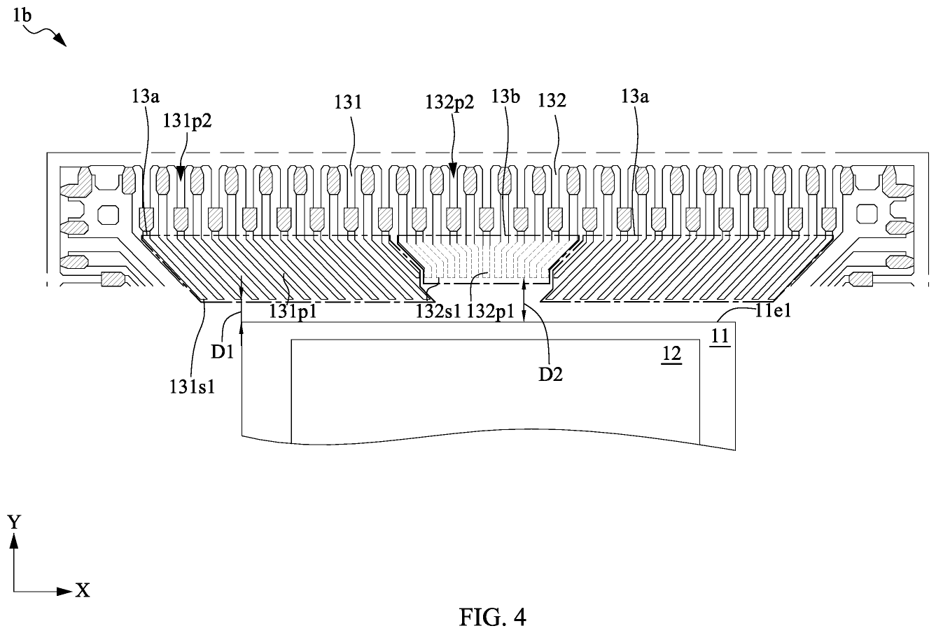

FIG. 4 illustrates a top view of a package structure 1b according to some embodiments of the present disclosure. The package structure 1b of FIG. 4 has a similar structure to that of the package structure 1a of FIG. 2A except that the lead 131 may overlap the lead 132 along the Y direction.

The inner portion 131p1 of the lead 131 may have an end 131s1 facing the edge 11e1 of the die paddle 11. The inner portion 132p1 of the lead 132 may have an end 132s1 facing the edge 11s1 of the die paddle 11. The end 131s1 of the inner portion 131p1 and the die paddle 11 may have a distance D1 therebetween along the Y direction. The end 132s1 of the inner portion 132p1 and the die paddle 11 may have a distance D2 therebetween along the Y direction. In some embodiments, the distance D1 may be different from the distance D2. In some embodiments, the distance D1 may be less than the distance D2. In some embodiments, a portion of the lead 131 may be disposed between the lead 132 and the die paddle 11. In some embodiments, the side (not annotated) of the outer portion 131p2 may be substantially aligned with the side (not annotated) of the outer portion 132p2 along the X direction.

In this embodiment, the lead 131 may further be lengthened to reduce the distance between the lead 131 and the die paddle 11. As a result, the length of the wire may further be reduced to enlarge the process window of manufacturing the package structure 1b.

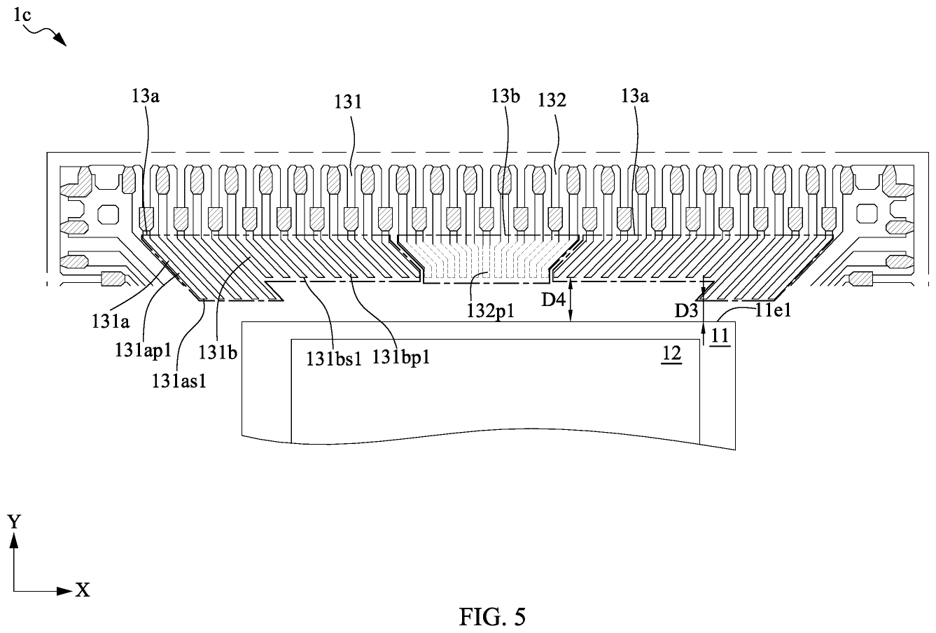

FIG. 5 illustrates a top view of a package structure 1c according to some embodiments of the present disclosure. The package structure 1c of FIG. 5 has a similar structure to that of the package structure 1d of FIG. 4 except that the package structure 1c may include leads 131a and leads 131b.

The leads 131a and 131b may be disposed within the high density lead region 13a. The lead 131a may have an inner portion 131ap1. The lead 131b may have an inner portion 131bp1. In some embodiments, the length of the inner portion 131ap1 may be greater than that of the inner portion 131bp1. The inner portion 131ap1 may have an end 131as1 facing the edge 11e1 of the die paddle 11. The inner portion 131bp1 may have an end 131bs1 facing the edge 11e1 of the die paddle 11. The end 131as1 of the inner portion 131ap1 and the die paddle 11 may have a distance D3 therebetween along the Y direction. The end 131bs1 of the lead 131bp1 and the die paddle 11 may have a distance D4 therebetween along the Y direction. In some embodiments, the distance D3 may be less than the distance D4. In some embodiments, the lead 131bp1 may overlap the lead 131ap1 along the Y direction.

In this embodiment, the lead 131 may have different lengths. As a result, the design of leads (e.g., 131a, 131b, and 132) may become more flexible to satisfy the layout of different products.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only and that practical implementations of the structures described herein can be spatially arranged in any orientation or manner, provided that the merits of embodiments of this disclosure are not deviated from by such an arrangement.

As used herein, the term “vertical” is used to refer to upward and downward directions, whereas the term “horizontal” refers to directions transverse to the vertical directions.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between the highest point and the lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit, and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a die bonding region; and
a first lead region extending along a first direction, wherein the first direction is along a first edge of the die bonding region, and wherein the first lead region comprises a first high density lead region and a first low density lead region, and the first high density lead region overlaps the first low density lead region in the first direction.

2. The package structure of claim 1, wherein the first high density lead region is closer to an end portion of the first lead region than the first low density lead region is.

3. The package structure of claim 2, wherein the first high density lead region comprises a plurality of first leads having a first pitch, the first low density lead region comprises a plurality of second leads having a second pitch greater than the first pitch.

4. The package structure of claim 3, wherein the first lead region has an inner region proximal to the die bonding region and an outer region distal from the die bonding region, and a pitch of the plurality of first leads in the outer region is substantially equal to a pitch of the plurality of second leads in the outer region.

5. The package structure of claim 4, wherein a pitch of the plurality of first leads in the inner region is less than a pitch of the plurality of second leads in the inner region.

6. The package structure of claim 1, wherein the first low density lead region is closer to a center of the first edge of the die bonding region than the first high density lead region is.

7. The package structure of claim 1, wherein the first lead region further comprises a second high density lead region overlapping the first low density lead region in the first direction, and wherein the first low density lead region is in between the first high density lead region and the second high density lead region.

8. The package structure of claim 3, further comprising:
a second lead region extending along a second direction, wherein the second direction is along a second edge of the die bonding region, and the first edge is not parallel to the second edge, and wherein the second lead region comprises a second high density lead region and a second low density lead region, and the second high density lead region overlaps the second low density lead region in the second direction.

9. The package structure of claim 3, wherein an amount of the plurality of first leads is greater than or equal to an amount of the plurality of second leads.

10. A package structure, comprising:
a die paddle;
a first lead region located at a first side of the die paddle, wherein the first lead region comprises a first inner region and a first outer region, and the first inner region is closer to the die paddle than the first outer region is; and
a plurality of first leads disposed within the first lead region and extending from the first outer region to the first inner region,
and wherein a pitch of the plurality of first leads in the first outer region is greater than a pitch of the plurality of first leads in the first inner region.

11. The package structure of claim 10, further comprising:
a second lead region located at a second side, different from the first side, of the die paddle, wherein the second lead region comprises a second inner region and a second outer region, and the second inner region is closer to the die paddle than the second outer region is;
a plurality of second leads disposed within the second lead region and extending from the second outer region to the second inner region,
and wherein a pitch of the plurality of second leads in the second outer region is greater than a pitch of the plurality of second leads in the second inner region.

12. A package structure, comprising:
a die paddle;
a plurality of first leads, wherein at least one of the plurality of first leads has a first inner portion proximal to the die paddle and a first outer portion distal from the die paddle; and
a plurality of second leads, wherein at least one of the plurality of second leads has a second inner portion proximal to the die paddle and a second outer portion distal from the die paddle,
wherein from a top view, the first outer portion is aligned with the second outer portion along a first direction which is along a first edge of the die paddle, and the first inner portion overlaps the second inner portion along a second direction not parallel to the first direction.

13. The package structure of claim 12, wherein a distance between an end of the first inner portion of the at least one the plurality of first leads and the die paddle is greater than a distance between an end of the second inner portion of the at least one of the plurality of second leads and the die paddle.

14. The package structure of claim 13, wherein a width of the first inner portion of the at least one the plurality of first leads is less than a width of the second inner portion of the at least one of the plurality of second leads.

15. The package structure of claim 13, further comprising:
a first wedge bond bonded to the first inner portion of the at least one of the plurality of first leads, wherein the first wedge bond has a portion overlapping an edge of the first inner portion of the at least one of the plurality of first leads.

16. The package structure of claim 15, further comprising:
a second wedge bond bonded to the second inner portion of the at least one of the plurality of second leads, wherein the second wedge bond is located within the second inner portion of the at least one of the plurality of second leads.

17. The package structure of claim 13, further comprising:
a first wedge bond bonded to the first inner portion of at least one of the plurality of first leads; and
a second wedge bond bonded to the second inner portion of at least one of the plurality of second leads,
wherein a distance between the first wedge bond and an edge of the first inner portion is less than a distance between the second wedge bond and an edge of the second inner portion.

18. The package structure of claim 13, wherein an end of the first outer portion is aligned with an end of the second outer portion.

19. The package structure of claim 13, wherein a pitch at the first inner portion of the plurality of first leads is different from a pitch at the second inner portion of the plurality of second leads.

20. The package structure of claim 13, wherein the plurality of first leads are located closer to a corner of the die paddle than the plurality of second leads are.
